(19) United States
(12) Patent Application Publication
(10) Pub. No.: US 2026/0239628 A1
(43) Pub. Date: Aug. 13, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: CHIA YU LING, HSINCHU CITY (TW); MING-YEN CHUANG, HSINCHU CITY (TW); KATHERINE H. CHIANG, NEW TAIPEI CITY (TW)

(21) Appl. No.: 19/051,225

(22) Filed: Feb. 12, 2025

(51) Int. Cl. H10B 63/00

(52) U.S. Cl. CPC H10B 63/30

(57) ABSTRACT

A semiconductor device includes a capacitor and a transistor disposed over and coupled to the capacitor. The capacitor includes a bottom electrode, a top electrode, and a ferroelectric material layer between the bottom electrode and the top electrode. The ferroelectric material layer covers sidewalls and a top surface of the bottom electrode. The transistor is coupled to the top electrode of the capacitor. The transistor includes a gate, a semiconductor layer wrapped around the gate, and a dielectric layer between the gate and the semiconductor layer.

### BACKGROUND

Resistive random-access memory (RRAM) is a type of non-volatile memory that is being considered for use in next generation electronic devices. RRAM has a simple structure and is compatible with complementary metal-oxide-semiconductor (CMOS) logic processes, making it a promising candidate for future memory technology. An RRAM cell includes a dielectric data storage structure with variable resistance, placed between two electrodes. RRAM devices offer advantages such as fast write times, high endurance, low power consumption, and low susceptibility to damage from radiation. As integrated circuits become more powerful, there is a desire to maximize a number of RRAM devices within the IC, but current stack configurations may limit the integration density. Despite these challenges, RRAM is seen as a promising technology for the future of non-volatile memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor memory structure in accordance with aspects of the present disclosure in one or more embodiments.

FIG. 2 is a circuit diagram of a semiconductor memory structures in accordance with aspects of the present disclosure in one or more embodiments.

FIG. 3 is a cross-sectional view of a semiconductor structure including at least an RRAM cell and a portion of a back-end-of-line (BEOL) interconnect structure in accordance with aspects of the present disclosure in one or more embodiments.

FIGS. 4A and 4B are cross-sectional views of a portion of a semiconductor memory structure in operations in accordance with aspects of the present disclosure in one or more embodiments.

FIG. 5 is a flowchart representing a method for forming a semiconductor memory structure according to aspects of the present disclosure.

FIGS. 6, 7, 8, 9, 10, 11, 12A, 13A, 14A, 15A, 18A, 19A, 20A, 21 and 22 are cross-sectional views illustrating a semiconductor memory structure at various fabrication stages in a first plane in accordance with aspects of one or more embodiments of the present disclosure.

FIGS. 12B, 13B, 14B, 15B, 18B, 19B and 20B are plan views of the semiconductor memory structure at various fabrication stages in a second plane in accordance with aspects of one or more embodiments of the present disclosure, wherein FIG. 12B is the plan view of the structure at the stage shown in FIG. 12A, FIG. 13B is the plan view of the structure at the stage shown in FIG. 13A, FIG. 14B is the plan view of the structure at the stage shown in FIG. 14A, FIG. 15B is the plan view the structure at the stage shown in of FIG. 15A, FIG. 18B is the plan view of the structure at the stage shown in FIG. 18A, FIG. 19B is the plan view of the structure at the stage shown in FIG. 19A, and FIG. 20B is the plan view of the structure at the stage shown in FIG. 20A.

FIGS. 16A and 17A are cross-sectional views illustrating a semiconductor memory structure at various fabrication stages in a first plane in accordance with aspects of one or more embodiments of the present disclosure.

FIGS. 16B and 17B are plan views of the semiconductor memory structure at various fabrication stages in a second plane in accordance with aspects of one or more embodiments of the present disclosure, wherein FIG. 16B is the plan view of the structure at the stage shown in FIG. 16A, and FIG. 17B is the plan view of the structure at the stage shown in FIG. 17A.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a semiconductor memory structure and a method for forming the same. In some embodiments, the semiconductor memory structure includes a non-planar 1T1R configuration formed in a back-end-of-line (BEOL) interconnect structure. The 1T1R configuration including one transistor and one resistive memory provides several advantages. For example, it offers low power consumption, making it suitable for battery-powered devices and energy-efficient systems. Further, it achieves high storage density, allowing for more data to be stored in a smaller physical space. With fast read and write access times, it is suitable for high-performance computing and data storage applications. Its non-volatile nature ensures data retention even when power is removed, making it ideal for applications where data persistence is critical. Furthermore, the non-planar 1T1R configuration is 3D stackable; therefore, this scalability helps to further increase device density and higher-performance memory solutions in the future. In some embodiments, the method for forming the non-planar 1T1R configuration integrated in a BEOL interconnect structure is a logic-compatible process.

While the present disclosure discusses aspects of methods of forming an RRAM cell in the context of a BEOL process or middle-end-of-line (MEOL) process performed after, e.g., a FinFET formation process, other embodiments may utilize aspects of this disclosure with other semiconductor fabrication processes.

Please refer to FIG. 1, which is a cross-sectional view of a semiconductor memory structure in accordance with aspects of the present disclosure in one or more embodiments. In some embodiments, the semiconductor memory structure 100 is provided. The semiconductor memory structure 100 may be formed over a substrate (not shown). In some embodiments, the substrate (not shown) may be any type of semiconductor body (including, for example, silicon (Si), silicon germanium (SiGe), silicon-on-insulator (SOI), or like), such as a semiconductor wafer and/or one or more dies on a wafer, as well as any other type of semiconductor and/or epitaxial layers, suitable for such application.

In some embodiments, the substrate can include FEOL devices and can be a portion of an IC chip, a system-on-chip (SoC), or a portion of an SoC. In some embodiments, the substrate can be a substrate accommodating FEOL devices such as microprocessors, memories, and/or other IC devices. In some embodiments, the substrate can include various passive and active microelectronic devices, such as resistors, capacitors, inductors, diodes, p-type field-effect transistors (PFETs), n-type field-effect transistors (NFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, other suitable components, or combinations thereof. The transistors may be planar transistors or multi-gate transistors, such as fin-type FETs (FinFETs).

In some embodiments, a layer of a MEOL interconnect structure (not shown) can be formed over the substrate. The layer of the MEOL interconnect structure includes a plurality of connecting vias (not shown) disposed in an inter-layer dielectric (ILD) layer (not shown). The connecting vias are coupled to the FEOL devices. In some embodiments, the connecting vias can include a via-to-gate (VG), which generally refers to a contact to a gate structure. In other embodiments, the connecting via can include a via-to-drain (VD), which generally refers to a contact to a source/drain region. Accordingly, the FEOL devices can be electrically connected to a BEOL interconnect structure through the layer of the MEOL interconnect structure.

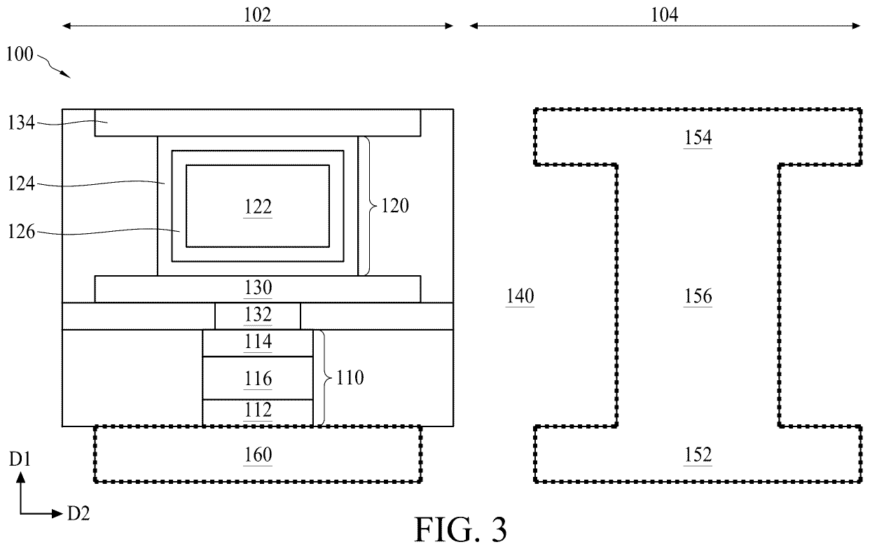

In some embodiments, a BEOL interconnect structure (shown in FIG. 3) is formed over the substrate and is electrically connected to the FEOL devices over the substrate. In some embodiments, the BEOL interconnect structure can include a plurality of metallization layers referred to, in ascending order, as the zeroth metallization layer M0, the first metallization layer M1, the Nth metallization layer Mn, and the (Mn+1)th metallization layer, and a plurality of connecting vias referred to as the zeroth via V0, the first via V1, and the Nth via Vn, wherein n is a positive integer. The Nth metallization layer Mn and the (Mn+1)th metallization layer Mn+1 can be electrically connected by the Nth via Vn. Further, the metallization layers Mn and Mn+1 and the connecting vias Vn can be formed in an inter-metal dielectric layer IMDn, which provides mechanical support and electrical isolation for the metallization layers Mn and Mn+1, and the connecting via Vn. In some embodiments, the semiconductor memory structure 100 is disposed in the BEOL interconnect structure.

The semiconductor memory structure 100 includes a resistive structure 110 and a transistor 120 electrically connected to each other. Further, the resistive structure 110 and the transistor 120 may be stacked in a direction D1 (i.e., a Z direction), with the transistor 120 disposed over the resistive structure 110, as shown in FIGS. 1 and 3. In some embodiments, the resistive structure 110 includes a first electrode 112, a second electrode 114 over the first electrode 112, and a dielectric layer 116 between the first electrode 112 and the second electrode 114. In some embodiments, each of the first electrode 112, the second electrode 114 and the dielectric layer 116 includes a flat-shaped configuration, but the disclosure is not limited thereto. In some embodiments, each of the first electrode 112, the second electrode 114 and the dielectric layer 116 may extend in a direction D2 (i.e., a X direction).

Each of the first electrode 112 and the second electrode 114 may include an oxide semiconductor material. In some embodiments, the first electrode 112 and the second electrode 114 may include a same oxide semiconductor material or conductive metal oxide. In such embodiments, the first electrode 112 and the second electrode 114 may include indium oxide (InO), but the disclosure is not limited thereto. In other embodiments, the first electrode 112 and the second electrode 114 may include different materials. For example but not limited thereto, in some embodiments, the first electrode 112 may include InO, while the second electrode 114 includes another oxide semiconductor material or another conductive metal oxide. In some embodiments, a thickness of the first electrode 112 may be between approximately 1 nanometer and approximately 100 nanometers, and a thickness of the second electrode 114 may be between approximately 1 nanometer and approximately 100 nanometers, but the disclosure is not limited thereto. In some embodiments, the thickness of the first electrode 112 and the thickness of the second electrode 114 may be equal, but the disclosure is not limited thereto.

The dielectric layer 116 includes dielectric materials. In some embodiments, the dielectric layer 116 includes high-k dielectric materials. In some embodiments, the dielectric layer 116 may include zirconium oxide, hafnium oxide (HfOx), aluminum oxide (AlOₓ), titanium oxide (TiO), tantalum oxide (TaO), gadolinium oxide (Gd₂O₃), barium titanate (BaTiO₃), lanthanum oxide (LaO₂), Yttrium oxide (Y₂O₃), hafnium zirconium oxide (HfZrO), hafnium lanthanum oxide (HfLaO), hafnium tantalum oxide (HfTaO), hafnium titanium oxide (HfTiO), or a combination thereof. In other some embodiments, the dielectric layer 116 may include silicon oxide, but the disclosure is not limited thereto. A thickness of the dielectric layer 116 may be between approximately 0.1 nanometer and approximately 10 nanometers, but the disclosure is not limited thereto.

The transistor 120 includes a gate 122, a semiconductor layer 124 wrapped around the gate 122, and a gate dielectric layer 126 between the gate 122 and the semiconductor layer 124. In some embodiments, the gate 122 may be referred to as a portion of a word line (WL), but the disclosure is not limited thereto. In some embodiments, the gate 122 includes metal materials or metallization materials such as W, Ru, titanium nitride (TiN), or combinations thereof, but the disclosure is not limited thereto. In some embodiments, the semiconductor layer 124 may include an oxide semiconductor layer. In some embodiments, the semiconductor layer 124 may include indium gallium zinc oxide (IGZO), or a similar conductive oxide semiconductor material such as indium tin oxide (ITO), indium tungsten oxide (IWO), indium zinc oxide (IZO), zinc tin oxide (ZTO) or a combination thereof, but the disclosure is not limited thereto. In some embodiments, the gate dielectric layer 126 may include a high-k dielectric material. In some embodiments, the gate dielectric layer 126 may include zirconium oxide, hafnium oxide, aluminum oxide, titanium oxide, tantalum oxide, Gd₂O₃, BaTiO₃, LaO₂, Y₂O₃, HfZrO, HfLaO, HfTaO, HfTiO, or a combination thereof. In some embodiments, the gate dielectric layer 126 includes one or more materials selected from aluminum oxide, hafnium oxide, tantalum oxide and zirconium oxide.

Referring to FIG. 1, in some embodiments, each of the semiconductor layer 124 and the gate dielectric layer 126 has an O-shaped configuration in a cross-sectional view (i.e., in the Y-Z plane cross-sectional view). In some embodiments, a bottom of the semiconductor layer 124 and a top of the semiconductor layer 124 are referred to as a source/drain region of the transistor 120. In such embodiments, portions of the semiconductor layer 124 between the top and the bottom are referred to as a channel region of the transistor 120.

In some embodiments, the semiconductor memory structure 100 further includes a conductive line 130 disposed between the transistor 120 and the resistive structure 110. In some embodiments, a via connector 132 is disposed between the resistive structure 110 and the transistor 120. Further, the via connector 132 is disposed between the second electrode 114 of the resistive structure 110 and the conductive line 130, as shown in FIG. 1. In such embodiments, the transistor 120 is electrically connected to the resistive structure 110 through the conductive line 130 and the via connector 132.

In some embodiments, the semiconductor memory structure 100 further includes a conductive line 134 disposed over and coupled to the transistor 120. In such embodiments, the conductive line 134 is coupled to the semiconductor layer 124 of the transistor 120, as shown in FIG. 1.

In some embodiments, the conductive line 130 may be referred to as a portion of a bit line (BL) of the semiconductor memory structure 100, the gate 122 of the transistor 120 may be referred to as a portion of a word line (WL) of the semiconductor memory structure 100, and the conductive line 134 may be referred to as a portion of a selective line (SL) of the semiconductor memory structure 100.

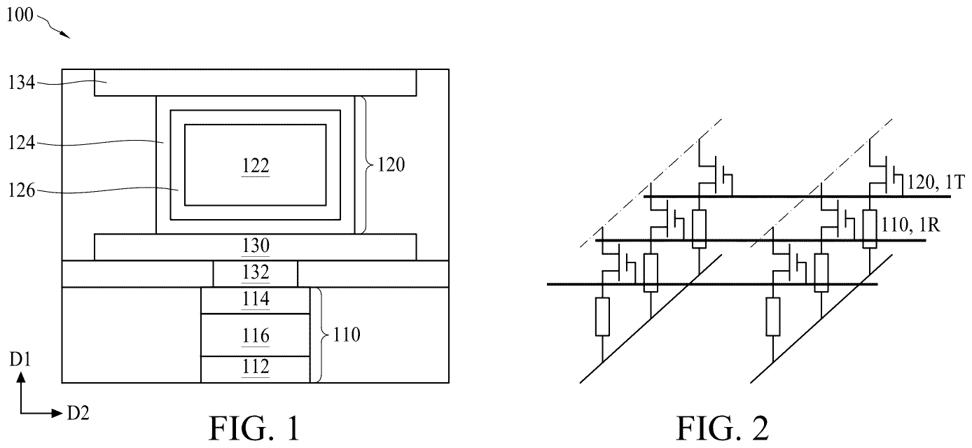

Accordingly, the semiconductor memory structure 100 including one resistive structure 110 and one transistor 120 is referred to as a non-planar 1T1R RAM memory cell, as shown in FIGS. 1 and 2, wherein FIG. 2 is a circuit diagram of the semiconductor memory structure 100 in accordance with aspects of the present disclosure in one or more embodiments. In some embodiments, the semiconductor memory structure 100 may be repeatedly or periodically arranged in directions (i.e., an X direction and Y direction), as shown in FIG. 2. It is concluded that a device density can be increased by the semiconductor memory structures 100 having the non-planar configuration.

Referring to FIG. 3, as mentioned above, the semiconductor memory structure 100 is disposed in a BEOL interconnect structure. Further, the semiconductor memory structure 100 is disposed in an insulating structure 140 including multiple insulating layers (i.e., an IMD layer, IMDn) of the BEOL interconnect structure. In some embodiments, the insulating structure 140 may include a first region 102, where the semiconductor memory structure 100 is disposed, and a second region 104, where metallization layers 152 and 154 (i.e., the Nth metallization layer Mn and the (N+1)th metallization layer Mn+1) are disposed. Further, a connecting via 156 (i.e., the nth connecting via Vn) is disposed in the insulating structure 140 in the second region 104, and electrically connects the metallization layers 152 and 154 to each other.

In some embodiments, the semiconductor memory structure 100 is physically separated from the metallization layers 152 and 154 and the connecting via 156. In some embodiments, the semiconductor memory structure 100 is electrically separated from the metallization layers 152 and 154 and the connecting via 156. In some embodiments, a top surface of the conductive line 134 is aligned (i.e., coplanar) with a top surface of the metallization layer 154. In some embodiments, another metallization layer 160 may be disposed in the insulating structure 140 and coupled to the semiconductor memory structure 100. In such embodiments, the metallization layer 160 may be coupled to the first electrode 112 of the resistive structure 110 of the semiconductor memory structure 100.

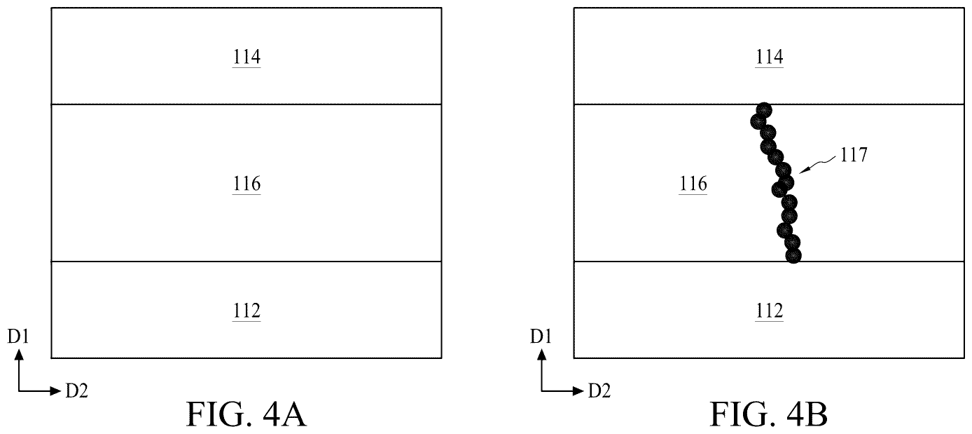

Referring to FIGS. 4A and 4B, in some embodiments, the dielectric layer 116 between the first electrode 112 and the second electrode 114 serves as a data storage layer. As mentioned above, the first electrode 112 is coupled to the lower metallization layer 160 of the BEOL interconnect structure, and the second electrode 114 is coupled to the upper metallization layer (i.e., the conductive line 130) of the BEOL interconnect structure through the via connector 132. The data storage layer (i.e., the dielectric layer) 116 is configured to store data states by undergoing reversible changes between a high resistive state associated with a first data state (e.g., a ‘0’) and a low resistive state associated with a second data state (e.g., a ‘1’). For example, during operation, to achieve a low resistive state within the data storage layer 116, a first set of bias conditions may be applied to the first electrode 112 and the second electrode 114. In some embodiments, when the first electrode 112 includes InO, the first set of bias conditions drive indium from the first electrode 112 into the data storage layer 116. Indium may cross the data storage layer and form a “bridge” between the first and second electrodes 112 and 114, thereby forming a conductive filament 117 of indium, as shown in FIG. 4B. Alternatively, to achieve a high resistive state within the data storage layer 116, a second set of bias conditions may be applied to the first electrode 112 and the second electrode 114. The second set of bias conditions breaks the conductive filament 117 by driving indium back into the first electrode 112 from the data storage layer 116, as shown in FIG. 4A.

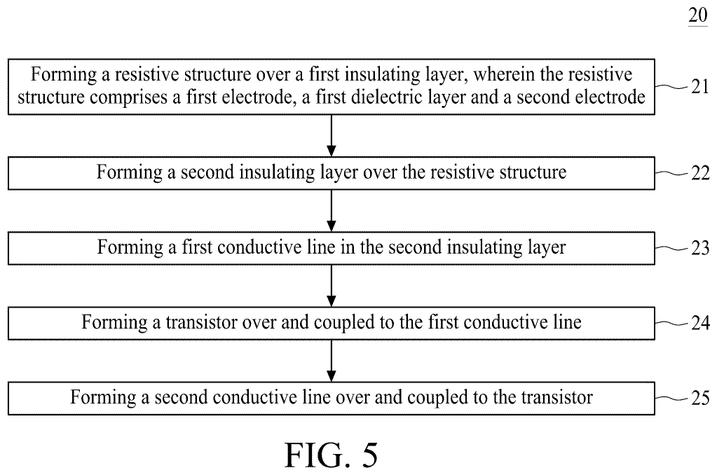

FIG. 5 is a flowchart representing a method for forming a semiconductor memory structure 20 in accordance with aspects of the present disclosure. The method 20 includes a number of operations (21, 22, 23, 24 and 25). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

In some embodiments, a semiconductor memory structure 200 may be formed by the method 20. Please refer to FIGS. 6, 7, 8, 9, 10, 11, 12A, 13A, 14A and 15A, which are cross-sectional views of the semiconductor memory structure 200 at various fabrication stages in a first plane (e.g., an X-Z plane) in accordance with aspects of one or more embodiments of the present disclosure.

Referring to FIG. 6, which is a cross-sectional view of an intermediate semiconductor structure 201 at a fabrication stage in accordance with aspects of one or more embodiments of the present disclosure. In some embodiments, in operation 21, a resistive structure is formed over a first insulating layer. In some embodiments, operation 21 may include further operations. For example, an insulating layer 106 is provided or formed over a substrate (not shown). In some embodiments, the substrate may be similar to that described above; therefore, repeated descriptions of such details are omitted for brevity. In some embodiments, FEOL devices can be formed over the substrate, a MEOL interconnect structure (not shown) can be formed over the substrate, and a BEOL interconnect structure (not shown) is formed over the substrate and electrically connected to the FEOL devices over the substrate through the MEOL interconnect structure. Details of the FEOL devices, the MEOL interconnect structure, and the BEOL interconnect structure may be similar to those described above; therefore, repeated descriptions are omitted for brevity.

Still referring to FIG. 6, in some embodiments, the insulating layer 106 may be a portion of an inter-metal dielectric (IMD) layer of the BEOL interconnect structure. In some embodiments, a metallization layer 160 may be formed in the insulating layer 106. In some embodiments, the metallization layer 160 may be formed by removing a portion of the insulating layer 106 to form an opening (not shown), filling the opening with a conductive material, and removing superfluous portions of the conductive material by a planarization operation such as, for example but not limited thereto, a chemical-mechanical polish (CMP).

In some embodiments, a first oxide semiconductor layer 112′ is formed over the insulating layer 106. The first oxide semiconductor layer 112′ may overlap and couple to the metallization layer 160, but the disclosure is not limited thereto. A dielectric layer 116′ is subsequently formed over the first oxide semiconductor layer 112′. Further, a second oxide semiconductor layer 114′ is formed over the dielectric layer 116′. In some embodiments, the first and second oxide semiconductor layers 112′ and 114′ may include a same material. For example but not limited thereto, both the first and the second oxide semiconductor layers 112′ and 114′ include InO. In other embodiments, the first and the second oxide semiconductor layers 112′ and 114′ may include different materials. For example but not limited thereto, the first oxide semiconductor layer 112′ may include InO, and the second oxide semiconductor layer 114′ may include an oxide semiconductor material other than InO. The dielectric layer 116′ between the first and the second oxide semiconductor layers 112′ and 114′ may include a high-k dielectric material. In some embodiments, the high-k dielectric material may be similar to those described above; therefore, repeated descriptions are omitted for brevity.

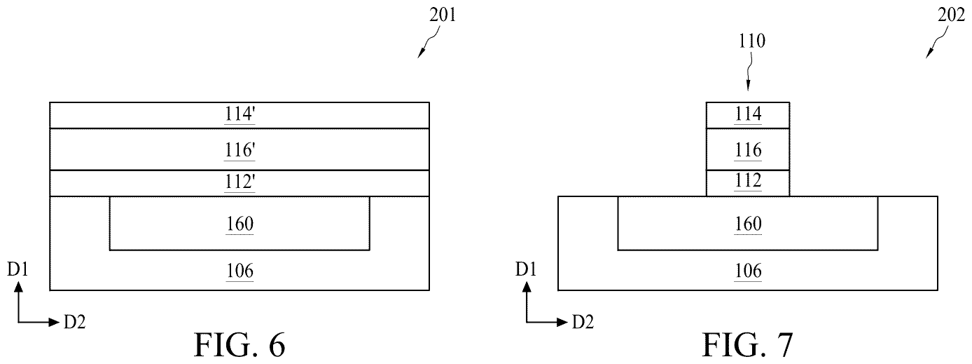

Referring to FIG. 7, which is a cross-sectional view of an intermediate semiconductor structure 202 at a fabrication stage in accordance with aspects of one or more embodiments of the present disclosure, in some embodiments, the first oxide semiconductor layer 112′, the dielectric layer 116′ and the second oxide semiconductor layer 114′ are patterned, thereby forming a resistive structure 110 over the insulating layer 106. The resistive structure 110 includes a first electrode (i.e., the first oxide semiconductor layer) 112, a data storage layer (i.e., the dielectric layer) 116, and a second electrode (i.e., the second oxide semiconductor layer) 114.

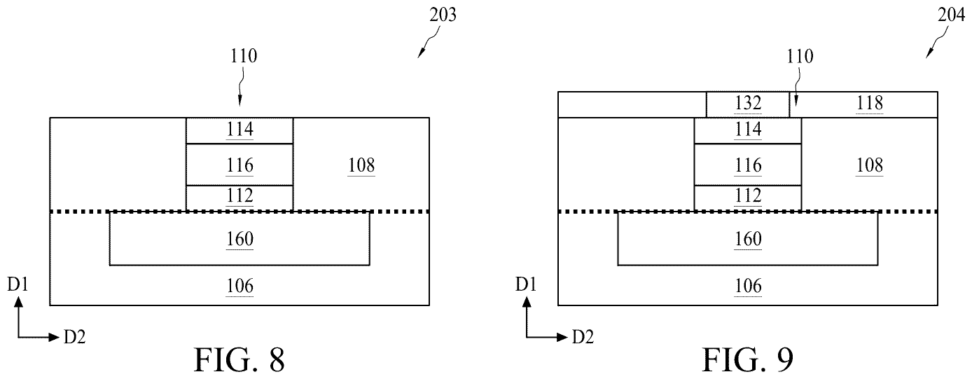

Please refer to FIGS. 8 and 9, which are cross-sectional views of intermediate semiconductor structures 203 and 204 at fabrication stages in accordance with aspects of one or more embodiments of the present disclosure. In some embodiments, another insulating layer 108 is formed over the insulating layer 106. In some embodiments, the insulating layer 108 may include a material same as that of the insulating layer 106, but the disclosure is not limited thereto. In some embodiments, the insulating layer 108 may be formed to cover the resistive structure 110. A planarization such as a chemical mechanical polish (CMP) may be performed on the insulating layer 108 such that a top surface of the insulating layer 108 is aligned (i.e., coplanar) with a top surface of the second electrode 114 of the resistive structure 110.

Referring to FIG. 9, in some embodiments, a patterned insulating layer 118 may be formed over the insulating layer 108. Further, the patterned insulating layer 118 may include a material different from that of the insulating layer 108. For example but not limited thereto, the patterned insulating layer 118 may include silicon nitride, while the insulating layer 108 includes silicon oxide. In some embodiments, the patterned insulating layer 118 includes an opening (not shown) exposing a portion of the second electrode 114. In some embodiments, a dimension (e.g., a width, a length or a diameter) of the opening is less than a dimension of the underlying second electrode 114, but the disclosure is not limited thereto.

Still referring to FIG. 9, in some embodiments, a via connector 132 is formed in the opening and coupled to the second electrode 114. In some embodiments, the opening is filled with a conductive material, and superfluous portions of the conductive material are removed by a planarization operation such as, for example but not limited thereto, a CMP. As shown in FIG. 9, a dimension (e.g., a width, a length or a diameter) of the via connector 132 is less than a dimension of the underlying second electrode 114, but the disclosure is not limited thereto.

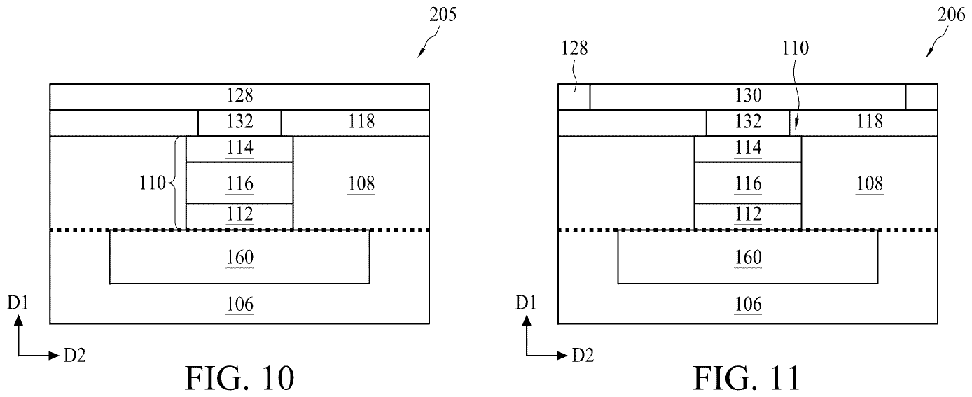

Please refer to FIG. 10, which is a cross-sectional view of an intermediate semiconductor structure 205 at a fabrication stage in accordance with aspects of one or more embodiments of the present disclosure. In some embodiments, in operation 22, an insulating layer 128 is formed over the resistive structure 110. As shown in FIG. 10, the insulating layer 128 is formed over the patterned insulating layer 118 and the via connector 132. In some embodiments, a material of the insulating layer 128 is different from that of the patterned insulating layer 118, but the disclosure is not limited thereto. For example but not limited thereto, when the patterned insulating layer 118 includes silicon nitride, the insulating layer 128 may include silicon oxide.

Please refer to FIG. 11, which is a cross-sectional view of an intermediate semiconductor structure 206 at a fabrication stage in accordance with aspects of one or more embodiments of the present disclosure. In some embodiments, in operation 23, a first conductive line is formed in the insulating layer 128. In some embodiments, the insulating layer 128 is patterned to form an opening (not shown) exposing the via connector 132. A conductive material is formed to fill the opening and a planarization, such as a CMP, is subsequently performed. Accordingly, a conductive line 130 (i.e., the first conductive line) is formed in the insulating layer 128. As shown in FIG. 11, in some embodiments, the conductive line 130 is coupled to the via connector 132. In some embodiments, the conductive line 130 is electrically connected to the resistive structure 110 (i.e., the second electrode 114 of the resistive structure 110) through the via connector 132. In some embodiments, the conductive line 130 may serve as a bit line of the semiconductor memory structure.

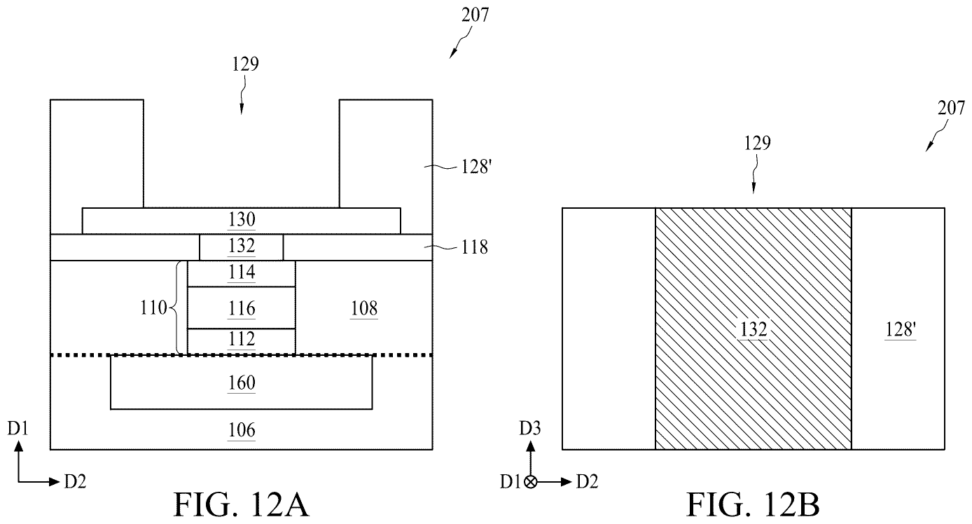

In some embodiments, in operation 24, a transistor is formed over and coupled to the resistive structure 110. In some embodiments, operation 24 includes further operations. For example, as shown in FIGS. 12A and 12B, which are cross-sectional views of different planes of an intermediate semiconductor structure 207 at a fabrication stage in accordance with aspects of one or more embodiments of the present disclosure, an insulating layer is formed over the insulating layer 128 and the conductive line 130. In some embodiments, the insulating layer may include an insulating material same as that of the insulating layer 128. In such embodiments, a stack including at least the two insulating layers may be referred to as one insulating layer 128′, as shown in FIG. 12A.

Still referring to FIGS. 12A and 12B, an opening 129 is formed in the insulating layer 128′. In some embodiments, the opening 129 may include a strip configuration that extends in a direction D3. In some embodiments, a dimension of the opening 129 may be between approximately 0.3 nanometers and approximately 150 nanometers, but the disclosure is not limited thereto. In some embodiments, the dimension may be a width of the opening 129 that is measured along the direction D2. Further, a portion of the conductive line 130 is exposed through the opening 129.

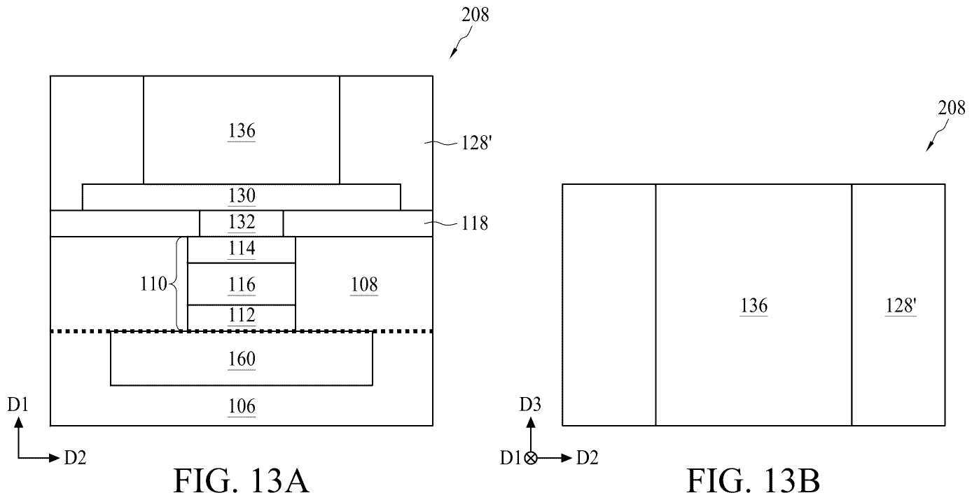

Please refer to FIGS. 13A and 13B, which are cross-sectional views of different planes of an intermediate semiconductor structure 208 at a fabrication stage in accordance with aspects of one or more embodiments of the present disclosure. In some embodiments, a sacrificial layer 136 is formed to fill the opening 129. In some embodiments, the sacrificial layer 136 includes a material different from that of the insulating layer 128′. For example but not limited thereto, the sacrificial layer 136 may include silicon nitride, while the insulating layer 128′ includes silicon oxide. In some embodiments, the sacrificial layer 136 may be formed to fill the opening 129 and further cover the insulating layer 128′, and a planarization operation is performed to remove superfluous portions of the sacrificial layer 136. Accordingly, a top surface of the sacrificial layer 136 may be aligned (i.e., coplanar) with a top surface of the insulating layer 128′, as shown in FIG. 13A.

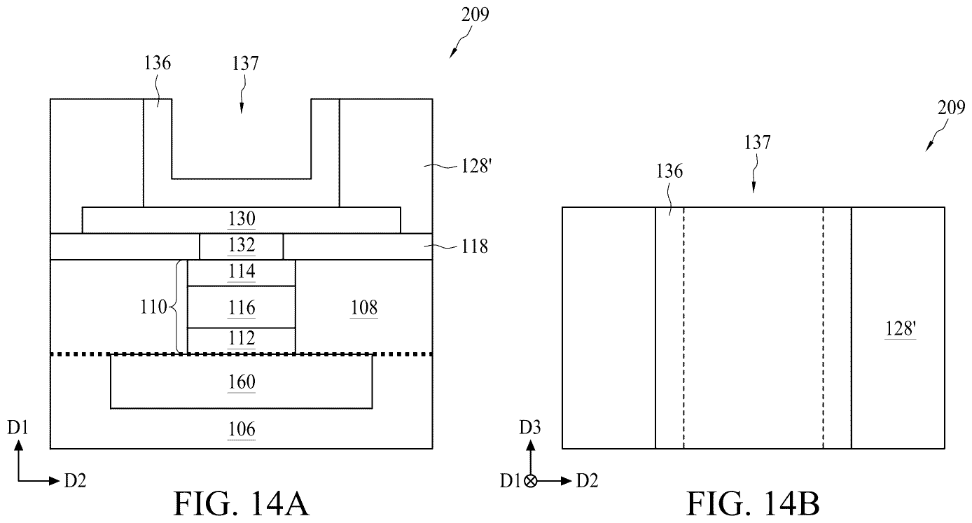

Please refer to FIGS. 14A and 14B, which are cross-sectional views of different planes of an intermediate semiconductor structure 209 at a fabrication stage in accordance with aspects of one or more embodiments of the present disclosure. In some embodiments, a portion of the sacrificial layer 136 is removed to form an opening 137. In some embodiments, the sacrificial layer 136 may include a U-shaped configuration, as shown in FIG. 14A. In some embodiments, a dimension of a topmost portion of the U-shaped sacrificial layer 136 is between approximately 0.1 nanometers and approximately 10 nanometers, but the disclosure is not limited thereto. In some embodiments, the dimension is a width measured in the direction D2.

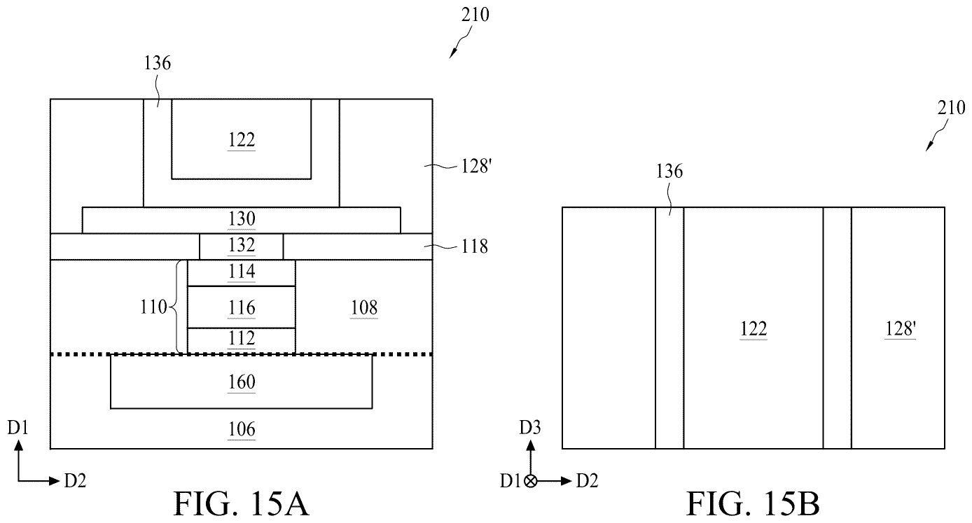

Please refer to FIGS. 15A and 15B, which are cross-sectional views of different planes of an intermediate semiconductor structure 210 at a fabrication stage in accordance with aspects of one or more embodiments of the present disclosure. In some embodiments, a conductive layer is formed to fill the opening 129. In some embodiments, a planarization operation may be performed to remove superfluous portions of the conductive layer, thereby forming a gate 122 over the sacrificial layer 136, as shown in FIG. 15A. Further, portions of the sacrificial layer 136 are exposed, and the top surface of the sacrificial layer 136, the top surface of the insulating layer 128′ and a top surface of the gate 122 may be aligned (i.e., coplanar) with each other. In some embodiments, a dimension of the gate 122 may be between approximately 0.1 nanometers and approximately 100 nanometers, but the disclosure is not limited thereto. In some embodiments, the dimension may be a width of the gate 122 that is measured along the direction D2.

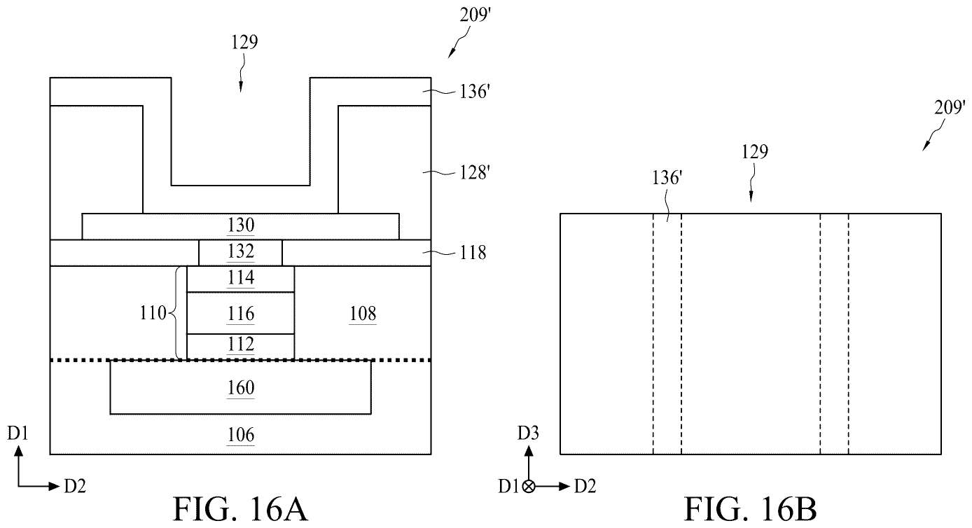

Please refer to FIGS. 16A and 16B, which are cross-sectional views of different planes of an intermediate semiconductor structure 209′ at a fabrication stage subsequent to that shown in FIGS. 12A and 12B. In some embodiments, after the forming of the opening 129, a sacrificial layer 136 is conformally formed in the opening 129. In such embodiments, a bottom and sidewalls of the opening 129 are covered by the sacrificial layer 136′. In some embodiments, a dimension of the sacrificial layer 136′ is between approximately 0.1 nanometers and approximately 10 nanometers, but the disclosure is not limited thereto. In some embodiments, the dimension of the sacrificial layer 136′ is a thickness of the sacrificial layer 136′ that is measured along the direction D1.

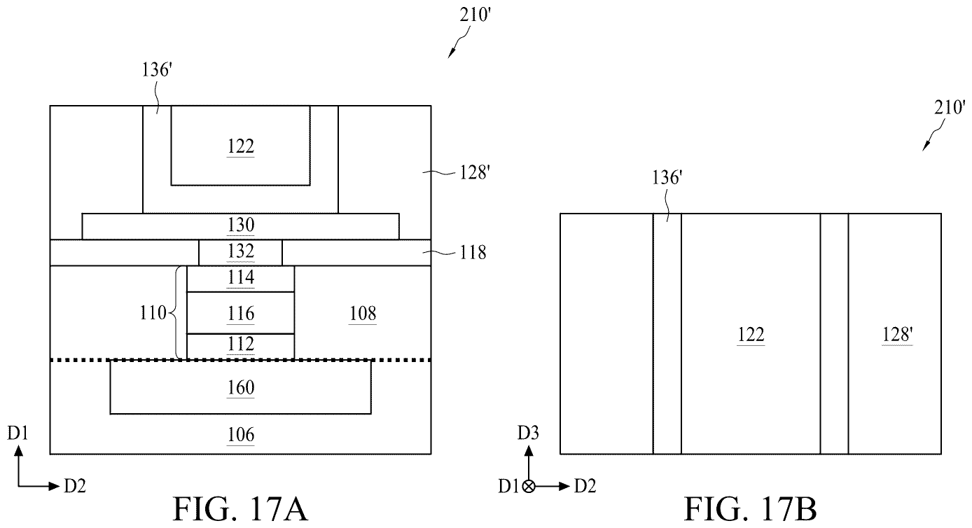

Please refer to FIGS. 17A and 17B, which are cross-sectional views of different planes of an intermediate semiconductor structure 210′ at a fabrication stage in accordance with aspects of one or more embodiments of the present disclosure. In some embodiments, a conductive layer is formed to fill the opening 129. In some embodiments, a planarization operation may be performed to remove superfluous portions of the conductive layer, thereby forming a gate 122 over the sacrificial layer 136′, as shown in FIG. 17A. Further, portions of the sacrificial layer 136′ are exposed, and a top surface of the gate 122, the top surface of the insulating layer 128′ and a topmost surface of the sacrificial layer 136′ may be aligned (i.e., coplanar) with each other.

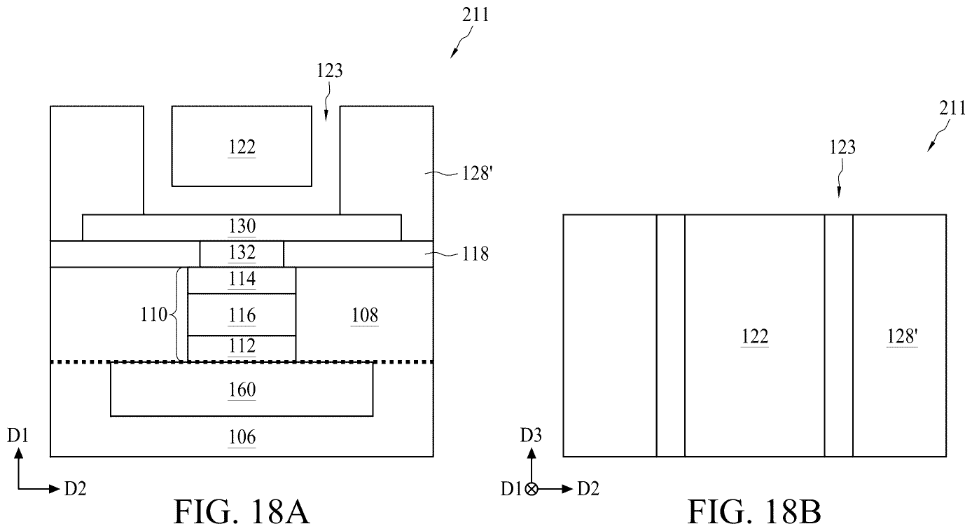

Please refer to FIGS. 18A and 18B, which are cross-sectional views of different planes of an intermediate semiconductor structure 211 at a fabrication stage subsequent to that shown in FIGS. 15A and 15B or in FIGS. 17A and 17B in accordance with aspects of one or more embodiments of the present disclosure. As shown in FIG. 18A, the sacrificial layer 136 or 136′ is removed. An air gap 123 is formed after the removal of the sacrificial layer 136 or 136′. In some embodiments, it can be said that the gate 122 is suspended over and exposed through the air gap 123.

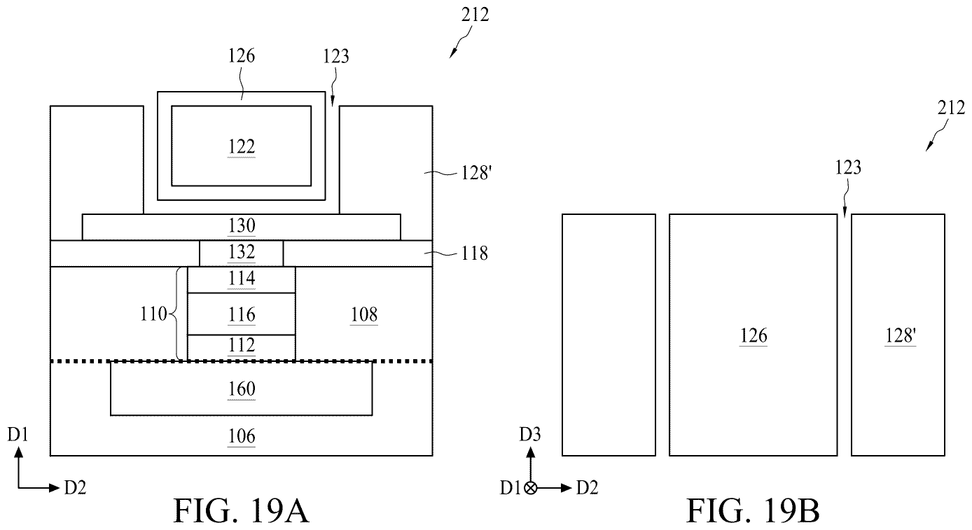

Please refer to FIGS. 19A and 19B, which are cross-sectional views of different planes of an intermediate semiconductor structure 212 at a fabrication stage in accordance with aspects of one or more embodiments of the present disclosure. In some embodiments, a dielectric layer 126 is formed to wrap around the gate 122. In some embodiments, the dielectric layer 126 may be formed by an atomic layer deposition (ALD), thereby forming the dielectric layer 126 over surfaces of the gate 122 that are exposed through the air gap 123. In some embodiments, a material of the dielectric layer 126 may be similar to that of the dielectric layer 126 mentioned above; therefore, repeated descriptions are omitted for brevity.

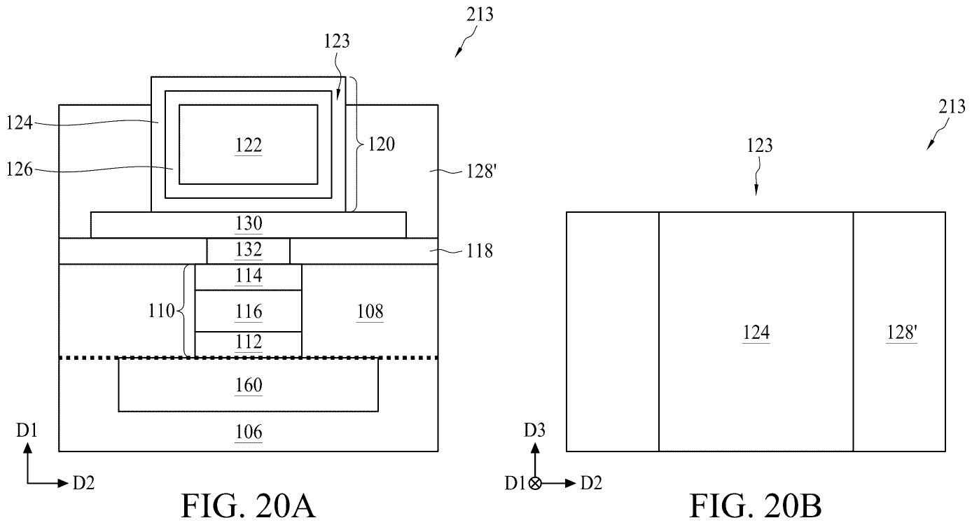

Please refer to FIGS. 20A and 20B, which are cross-sectional views of different planes of an intermediate semiconductor structure 213 at a fabrication stage in accordance with aspects of one or more embodiments of the present disclosure. In some embodiments, a semiconductor layer 124 is formed to wrap around the dielectric layer 126 and the gate 122. In some embodiments, the semiconductor layer 124 may be formed by an ALD, thereby forming the semiconductor layer 124 over surfaces of the dielectric layer 126 that are exposed through the air gap 123. Further, the air gap 123 is filled with the semiconductor layer 124 and the dielectric layer 126. In some embodiments, the semiconductor layer 124 may be an oxide semiconductor layer. In such embodiments, the oxide semiconductor layer may include a material similar to that of the semiconductor layer 124 described above; therefore, repeated descriptions are omitted for brevity.

In some embodiments, the gate 122, the dielectric layer 126 and the semiconductor layer 124 form a field effect transistor 120, as shown in FIG. 20A.

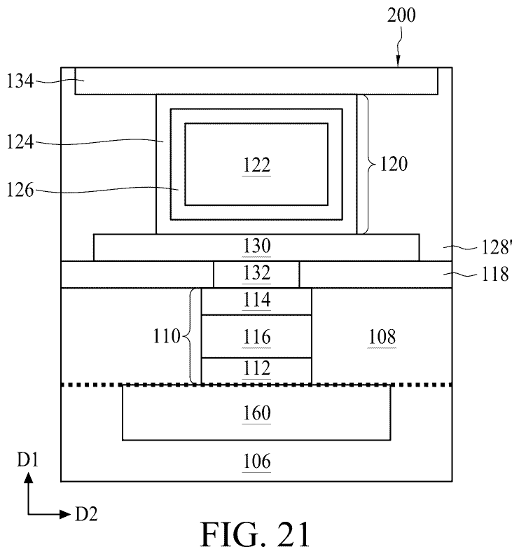

Please refer to FIG. 21, which is a cross-sectional view of a semiconductor memory structure 200 at a fabrication stage in accordance with aspects of one or more embodiments of the present disclosure. In some embodiments, in operation 25, a second conductive line is formed over and coupled to the transistor 120. In some embodiments, operation 25 includes further operations. For example, a third insulating layer may be formed over the semiconductor layer 124. In some embodiments, the third insulating layer includes a material same as that of the insulating layer 128′, but the disclosure is not limited thereto. In such embodiments, the third insulating layer may be referred to as a part of the insulating layer 128′, as shown in FIG. 21.

In some embodiments, a portion of the insulating layer 128′ is removed to form an opening (not shown) exposing a portion of the semiconductor layer 124. Subsequently, a conductive layer is formed to fill the opening, and a planarization operation is performed to remove superfluous portions of the conductive layer, thereby forming the conductive line 134, as shown in FIG. 21. Accordingly, the semiconductor memory structure 200 is formed. In some embodiments, the conductive line 130 serves as a bit line, and the conductive line 134 serves as a selective line for the semiconductor structure 200.

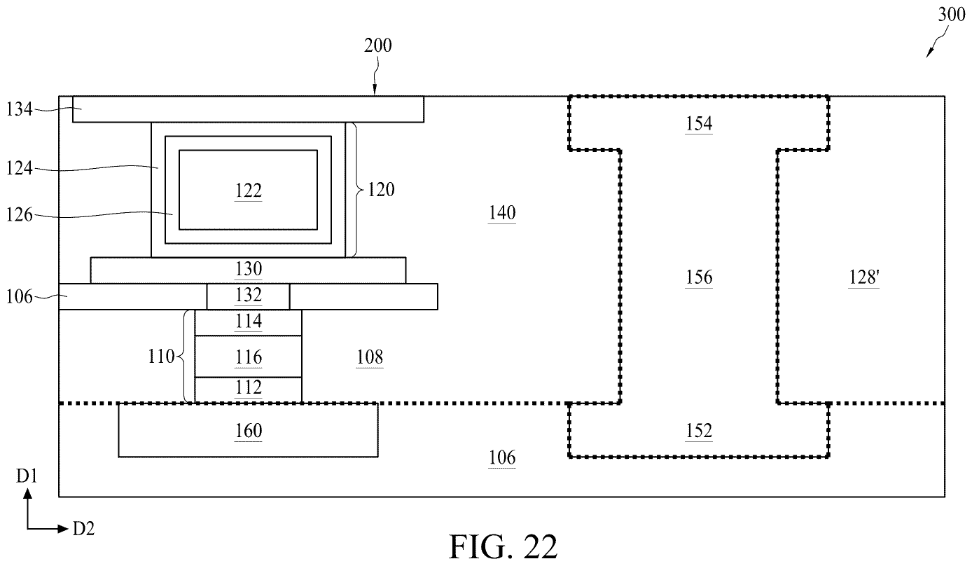

Please refer to FIG. 22, which is a cross-sectional view illustrating a semiconductor structure 300 in accordance with aspects of one or more embodiments of the present disclosure. In some embodiments, the semiconductor memory structure 200 is formed in a BEOL interconnect structure. In such embodiments, an IMD layer (i.e., the insulating layer 106) is formed, and metallization layers 152 and 160 are formed in the IMD layer 106. Additionally, via structures (not shown) may be formed to couple to the metallization layer 152 and a metallization layer 154. In some embodiments, an insulating structure 140 can be formed over the metallization layers 152 and 160. In some embodiments, the insulating structure 140 may be a multi-layered structure including at least the insulating layer 128′, as shown in FIG. 22.

In some embodiments, more metallization layers and via structures can be formed in the insulating structure 140 (including the insulating layer 128′). For example, the metallization layer 154 and a connecting via 156 are formed in the insulating structure (i.e., the insulating layer 128′). Further, the connecting via 156 is coupled to the metallization layer 152. Accordingly, the metallization layers 152 and 154 are electrically connected to each other through the connecting via 156. In some embodiments, the formation of the metallization layer 152, the connecting via 156 and the metallization layer 154 may be performed prior to the formation of the semiconductor memory structure 200. In some alternative embodiments, the formation of the metallization layer 152, the connecting via 156 and the metallization layer 154 may be performed after the formation of the semiconductor memory structure 200. In some embodiments, the formation of the metallization layers 154 and the connecting via 156 can include forming trenches and via openings in the insulating structure (i.e., the insulating layer 128′), filling the trench and the via openings with conductive materials, and performing a planarization such as a CMP operation. Further, in some embodiments, the metallization layer 152, the connecting via 156, and the metallization layer 154 are separated from the semiconductor memory structure 200.

Accordingly, the present disclosure provides a semiconductor memory structure and a method for forming the same. In some embodiments, the semiconductor memory structure includes a non-planar 1T1R configuration formed in a back-end-of-line (BEOL) interconnect structure. The 1T1R configuration including one transistor and one resistive memory provides several advantages. For example, it offers low power consumption, making it suitable for battery-powered devices and energy-efficient systems. Further, it achieves high storage density, allowing for more data to be stored in a smaller physical space. With fast read and write access times, it is suitable for high-performance computing and data storage applications. Its non-volatile nature ensures data retention even when power is removed, making it ideal for applications where data persistence is critical. Furthermore, the non-planar 1T1R configuration is 3D stackable; therefore, this scalability helps to further increase device density and higher performance memory solutions in the future. In some embodiments, the method for forming the non-planar 1T1R configuration integrated in a BEOL interconnect structure is a logic-compatible process.

In accordance with some embodiments, a semiconductor structure is provided. The semiconductor structure includes a resistive structure and a transistor disposed over and coupled to the resistive structure. The resistive structure includes a first electrode, a second electrode over the first electrode and a dielectric layer between the first electrode and the second electrode. The transistor is coupled to the first electrode of the resistive structure. The transistor includes a gate, a semiconductor layer wrapped around the gate, and a gate dielectric layer between the gate and the semiconductor layer. Each of the first electrode and the second electrode includes a first oxide semiconductor material.

In accordance with some embodiments, a method for forming a semiconductor structure is provided. The method includes following operations. A resistive structure is formed over a first insulating layer. The resistive structure includes a first electrode, a second electrode over the first electrode, and a first dielectric layer between the first electrode and the second electrode. Each of the first electrode and the second electrode includes an oxide semiconductor material. A first conductive line is formed over and coupled to the resistive structure. A transistor is formed over and coupled to the first conductive line. A second conductive line is formed over and coupled to the transistor.

In accordance with some embodiments, a method for forming a semiconductor structure is provided. The method includes following operations. A resistive structure is formed over an insulating structure. The resistive structure includes a first electrode, a second electrode over the first electrode, and a first dielectric layer between the first electrode and the second electrode. A bit line is formed over and coupled to the resistive structure. A word line is formed over the bit line. A selective line is formed over the word line. A first metallization layer and a via structure are formed in the insulating structure. The via structure is coupled to the first metallization layer. The first metallization layer and the via structure are separated from the resistive structure, the bit line, the word line and the selective line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a resistive structure comprising:
a first electrode;
a second electrode over the first electrode; and
a dielectric layer between the first electrode and the second electrode; and
a transistor disposed over and coupled to the first electrode of the resistive structure, wherein the transistor comprises:
a gate;
a semiconductor layer wrapped around the gate; and
a gate dielectric layer between the semiconductor layer and the gate,
wherein each of the first electrode and the second electrode comprises a first oxide semiconductor material.

2. The semiconductor structure of claim 1, further comprising:
a first conductive layer between the transistor and the resistive structure; and
a second conductive layer disposed over and coupled to the transistor.

3. The semiconductor structure of claim 2, further comprising a via connector disposed between the first conductive layer and the resistive structure, wherein the first conductive layer is electrically connected to the resistive structure through the via connector.

4. The semiconductor structure of claim 3, wherein the via connector is coupled to the second electrode of the resistive structure.

5. The semiconductor structure of claim 1, wherein the semiconductor layer of the transistor comprises a second semiconductor material.

6. The semiconductor structure of claim 1, wherein each of the semiconductor layer and the gate dielectric layer of the transistor has an O-shaped configuration in a cross-sectional view.

7. The semiconductor structure of claim 1, wherein the dielectric layer of the resistive structure comprises a high-k dielectric material.

8. A method for forming a semiconductor structure, comprising:
forming a resistive structure over a first insulating layer, wherein the resistive structure comprises a first electrode, a second electrode over the first electrode, and a first dielectric layer between the first electrode and the second electrode, wherein each of the first electrode and the second electrode comprises an oxide semiconductor material;
forming a first conductive line over and coupled to the resistive structure;
forming a transistor over and coupled to the first conductive line; and
forming a second conductive line over and coupled to the transistor.

9. The method of claim 8, wherein the forming of the resistive structure further comprises:
forming a first oxide semiconductor layer over the first insulating layer;
forming the first dielectric layer over the first oxide semiconductor layer;
forming a second oxide semiconductor layer over the first dielectric layer; and
patterning the first oxide semiconductor layer, the first dielectric layer and the second oxide semiconductor layer to form the resistive structure.

10. The method of claim 8, further comprising:
forming an isolation layer over the resistive structure; and
forming a via connector in the isolation layer,
wherein the first conductive line is electrically connected to the resistive structure through the via connector.

11. The method of claim 8, further comprising forming a second insulating layer over the resistive structure, wherein the first conductive line is formed in the second insulating layer.

12. The method of claim 8, wherein the forming of the transistor further comprises:
forming a third insulating layer over the resistive structure;
forming a first opening in the third insulating layer;
forming a sacrificial layer in the first opening;
forming a gate of the transistor over the sacrificial layer;
removing the sacrificial layer; and
forming a gate dielectric layer and a semiconductor layer wrapping around the gate.

13. The method of claim 12, wherein an air gap is formed after the removing of the sacrificial layer, and the gate dielectric layer and the semiconductor layer fill the air gap.

14. The method of claim 12, wherein the forming of the sacrificial layer further comprises:
filling the first opening with the sacrificial layer; and
removing a portion of the sacrificial layer to form a second opening,
wherein the second opening is filled with the gate of the transistor.

15. The method of claim 14, wherein the forming of the sacrificial layer further comprises:
conformally forming the sacrificial layer in the first opening to form a second opening,
wherein the second opening is filled with the gate of the transistor.

16. The method of claim 8, further comprising forming a fourth insulating layer over the transistor, wherein the second conductive line is formed in the fourth insulating layer.

17. A method for forming a semiconductor structure, comprising:
forming a resistive structure over an insulating structure, wherein the resistive structure comprises a first electrode, a second electrode over the first electrode, and a first dielectric layer between the first electrode and the second electrode;
forming a bit line over and coupled to the resistive structure;
forming a word line over the bit line;
forming a selective line over the word line; and
forming a first metallization layer and a via structure coupled to the first metallization layer in the insulating structure, wherein the first metallization layer and the via structure are separated from the resistive structure, the bit line, the word line and the selective line.

18. The method of claim 17, further comprising forming a second metallization layer and a third metallization layer separated from each other in the insulating structure, wherein the resistive structure is electrically connected to the second metallization layer, and the first metallization structure and the via structure are electrically connected to the third metallization layer.

19. The method of claim 17, wherein the forming of the first metallization layer and the via structure is performed prior to the forming of the resistive structure.

20. The method of claim 17, wherein the forming of the first metallization layer and the via structure is performed after the forming of the selective line.
